(19) United States
(12) Patent Application Publication
(10) Pub. No.: US 2016/0040045 A1
(43) Pub. Date: Feb. 11, 2016

(54) ADHESIVE FILM FOR UNDERFILL, ADHESIVE FILM FOR UNDERFILL INTEGRATED WITH TAPE FOR GRINDING REAR SURFACE, ADHESIVE FILM FOR UNDERFILL INTEGRATED WITH DICING TAPE, AND SEMICONDUCTOR DEVICE

(71) Applicant: NITTO DENKO CORPORATION, Osaka (JP)

(72) Inventors: Kosuke Morita, Ibaraki-shi (JP); Naohide Takamoto, Ibaraki-shi (JP); Hiroyuki Hanazono, Ibaraki-shi (JP); Akihiro Fukui, Ibaraki-shi (JP)

(21) Appl. No.: 14/782,292

(22) PCT Filed: Mar. 27, 2014
(86) PCT No.: PCT/JP2014/058851

§ 371 Date: Oct. 2, 2015

(30) Foreign Application Priority Data
Apr. 4, 2013 (JP) 2013-078872

(51) Int. Cl. C09J 133/12; C09J 163/00; H01L 23/31; H01L 21/56; H01L 23/29; C08K 3/36; H01L 21/683

(52) U.S. Cl. CPC C09J 133/12; C08K 3/36; C09J 163/00; H01L 21/6836; H01L 21/563; H01L 23/295; H01L 23/3142; H01L 2221/68327; H01L 2221/68377

(57) ABSTRACT

The present invention provides an adhesive film for underfill that is capable of increasing a glass transition temperature without losing flexibility. The present invention relates to an adhesive film for underfill containing resin components containing an epoxy resin having a number average molecular weight of 600 or less, a phenol resin having a number average molecular weight exceeding 500, and an elastomer in which a content of the epoxy resin in the resin components is 5 to 50% by weight, and the content of the phenol resin in the resin components is 5 to 50% by weight.

### TECHNICAL FIELD

The present invention relates to an adhesive film for underfill, an adhesive film for underfill integrated with a tape for grinding a rear surface, and an adhesive film for underfill integrated with a dicing tape, and a semiconductor device.

### BACKGROUND ART

In the manufacture of a flip-chip mounted semiconductor package, a semiconductor chip and a substrate are electrically connected to each other. Then, the space between the semiconductor chip and the substrate may be filled with a liquid underfill material (Patent Document 1).

However, the pitch of bumps of the semiconductor chip has become smaller in recent years. Therefore, it has been difficult to fill the unevenness of the bump formation surface with a method of filling the space with a liquid underfill material, and voids (air bubbles) may be generated. Accordingly, a technique has been proposed of filling the space between the semiconductor chip and the substrate with a sheet-shaped underfill material (Patent Document 2).

### PRIOR ART DOCUMENTS

### Patent Documents

Patent Document 1: JP-B2-4438973

Patent Document 2: JP-B2-4802987

### SUMMARY OF THE INVENTION

### Problems to be Solved by the Invention

Flexibility is required for a sheet-shaped underfill material. However, if the flexibility is increased, the glass transition temperature decreases, and the thermal reliability decreases. On the other hand, if the thermal reliability of an adhesive film for underfill is improved, the flexibility decreases, and the processability, etc., decrease.

The present invention has been made in consideration of the above-described problems, and an object thereof is to provide an adhesive film for underfill that is capable of obtaining an excellent thermal reliability without losing flexibility.

### Means for Solving the Problems

The present invention relates to an adhesive film for underfill containing resin components containing an epoxy resin having a number average molecular weight of 600 or less, a phenol resin having a number average molecular weight exceeding 500, and an elastomer; in which the content of the epoxy resin in the resin components is 5 to 50% by weight, and the content of the phenol resin in the resin components is 5 to 50% by weight.

In the present invention, the glass transition temperature can be increased because a specific amount of the phenol resin having a number average molecular weight exceeding 500 (phenol resin of a relatively high molecular weight) is compounded, and a good flexibility can be obtained because the a specific amount of the epoxy resin having a number average molecular weight of 600 or less (epoxy resin of relatively low molecular weight) is compounded. Further, compounding the elastomer enables maintaining the viscosity while also maintaining the flexibility.

The hydroxyl equivalent weight of the phenol resin is preferably 200 g/eq or more. If the hydroxyl equivalent weight is 200 g/eq or more, the distance between crosslinking points becomes large, and the contraction caused by thermal curing can be suppressed to improve the thermal reliability of the semiconductor element.

The phenol resin preferably contains a skeleton represented by Formula (I).

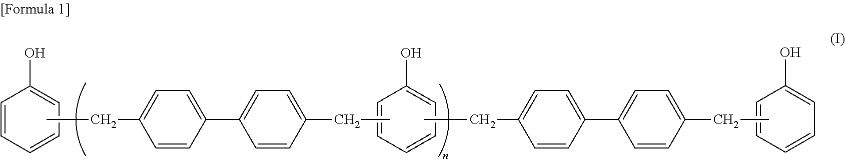

(In the formula, n represents an integer.) This makes it possible to maintain the glass transition point. Therefore, the thermal reliability can be improved further.

The epoxy resin is preferably a bisphenol A epoxy resin or a bisphenol F epoxy resin. This makes it possible to obtain good thermal reliability while improving the flexibility.

The content of the elastomer in the resin components is preferably 10 to 40% by weight. If the content of the elastomer is within this range, high thermal reliability can be obtained while maintaining the flexibility.

The elastomer is preferably an acrylic resin. This makes it possible to improve the heat resistance and the flexibility while maintaining the electrical reliability.

When the viscosity of the adhesive film for underfill is measured at 40 to 100° C., a temperature preferably exists at which the viscosity becomes 20,000 Pa·s or less. If a temperature exists at which the viscosity becomes 20,000 Pa·s or less, the unevenness of the adherend can be filled without voids. The minimum viscosity at 100 to 200° C. is preferably 100 Pa·s or more. If the minimum viscosity is 100 Pa·s or more, the generation of voids caused by outgas from the adhesive film can be suppressed.

The adhesive film for the underfill preferably contains 30 to 70% by weight of an inorganic filler. When the content of the inorganic filler is 30% by weight or more, the characteristics of the thermally cured product can be improved, and the thermal reliability can be improved. When the content is 70% by weight or less, good flexibility can be obtained, and the unevenness of the bump formation surface can be suitably filled.

The present invention also relates to an adhesive film for underfill integrated with a tape for grinding a rear surface having the adhesive film for underfill and the tape for grinding the rear surface, in which the adhesive film for underfill is provided on the tape for grinding the rear surface. When the adhesive film for underfill and the tape for grinding the rear surface are integrally used, the productivity can be improved.

The present invention also relates to an adhesive film for underfill integrated with a dicing tape having the adhesive film for underfill and the dicing tape, in which the adhesive film for underfill is provided on the dicing tape. When the adhesive film for underfill and the dicing tape are integrally used, the productivity can be improved.

The present invention also relates to a semiconductor device that is manufactured by using the adhesive film for underfill.

The present invention also relates to a semiconductor device that is manufactured by using the adhesive film for underfill integrated with the tape for grinding the rear surface.

The present invention also relates to a semiconductor device that is manufactured by using the adhesive film for underfill integrated with the dicing tape.

### BRIEF DESCRIPTION OF THE DRAWINGS

FIG. 1 is a schematic cross sectional view of an adhesive film for underfill integrated with a tape for grinding a rear surface.

FIG. 2A is a view showing one step of a method for manufacturing a semiconductor device using the adhesive film for underfill integrated with the tape for grinding the rear surface.

FIG. 2B is a view showing one step of the method for manufacturing the semiconductor device using the adhesive film for underfill integrated with the tape for grinding the rear surface.

FIG. 2C is a view showing one step of the method for manufacturing the semiconductor device using the adhesive film for underfill integrated with the tape for grinding the rear surface.

FIG. 2D is a view showing one step of the method for manufacturing the semiconductor device using the adhesive film for underfill integrated with the tape for grinding the rear surface.

FIG. 2E is a view showing one step of the method for manufacturing the semiconductor device using the adhesive film for underfill integrated with the tape for grinding the rear surface.

FIG. 2F is a view showing one step of the method for manufacturing the semiconductor device using the adhesive film for underfill integrated with the tape for grinding the rear surface.

FIG. 2G is a view showing one step of the method for manufacturing the semiconductor device using the adhesive film for underfill integrated with the tape for grinding the rear surface.

FIG. 3 is a schematic cross sectional view of an adhesive film for underfill integrated with a dicing tape.

FIG. 4A is a view showing one step of a method for manufacturing the semiconductor device using the adhesive film for underfill integrated with the dicing tape.

FIG. 4B is a view showing one step of the method for manufacturing the semiconductor device using the adhesive film for underfill integrated with the dicing tape.

FIG. 4C is a view showing one step of the method for manufacturing the semiconductor device using the adhesive film for underfill integrated with the dicing tape.

FIG. 4D is a view showing one step of the method for manufacturing the semiconductor device using the adhesive film for underfill integrated with the dicing tape.

### MODE FOR CARRYING OUT THE INVENTION

[Adhesive Film for Underfill]

The adhesive film for underfill of the present invention contains resin components containing an epoxy resin having a number average molecular weight of 600 or less, a phenol resin having a number average molecular weight exceeding 500, and an elastomer.

In the present invention, the glass transition temperature can be increased because a specific amount of the phenol resin having a number average molecular weight exceeding 500 (phenol resin of relatively high molecular weight) is compounded, and a good flexibility can be obtained because a specific amount of the epoxy resin having a number average molecular weight of 600 or less (epoxy resin of a relatively low molecular weight) is compounded. Further, compounding the elastomer enables maintaining the viscosity while also maintaining the flexibility.

The number average molecular weight of the epoxy resin is 600 or less, preferably 500 or less, and more preferably 400 or less. Because the number average molecular weight is 600 or less, good flexibility can be obtained. The lower limit of the number average molecular weight of the epoxy resin is not especially limited, and for example, 300 or more.

The number average molecular weight is obtained based on a standard polystyrene measured by gel permeation chromatography (GPC). The gel permeation chromatography is performed by using four columns of TSK G2000H HR, G3000H HR, G4000H HR, and GMH-H HR (all manufactured by TOSOH CORPORATION) that are connected in series and using tetrahydrofuran as an eluent under the conditions of flow velocity of 1 ml/min, temperature of 40° C., tetrahydrofuran solution having a sample concentration of 0.1% by weight, and sample injection amount of 500 μl. A differential refractometer is used as a detector.

The epoxy equivalent weight of the epoxy resin having a number average molecular weight of 600 or less is not especially limited; however, it is preferably 100 g/eq or more, and more preferably 150 g/eq or more. If the epoxy equivalent weight is less than 100 g/eq, the crosslinking points become dense, and there is a possibility that the thermal reliability may not be obtained due to curing contraction. The upper limit of the epoxy equivalent weight is preferably 500 g/eq or less, and more preferably 300 g/eq or less. If the epoxy equivalent weight exceeds 1,000 g/eq, the crosslinking points become sparse, and there is a possibility that sufficient thermal reliability may not be obtained.

Examples of the epoxy resin having a number average molecular weight of 600 or less include a bifunctional epoxy resin or a multifunctional epoxy resin such as a bisphenol A type, a bisphenol F type, a bisphenol S type, a brominated bisphenol A type, a hydrogenated bisphenol A type, a bisphenol AF type, a bisphenyl type, a naphthalene type, a fluorene type, a phenol novolak type, an o-cresol novolak type, a trishydroxyphenylmethane type, and a tetraphenylolethane type; and an epoxy resin such as a hydantoin type, a trisglycidylisocyanurate type, and a glycidylamine type. These may be used either alone or in combination of two or more thereof. Among these, a bisphenol A epoxy resin and a bisphenol F epoxy resin are preferable because the viscosity is low at normal temperature and the handling property is good.

The content of the epoxy resin having a number average molecular weight of 600 or less in the resin components is 5% by weight or more, and preferably 6% by weight or more. Because the content of the epoxy resin is 5% by weight or more, good flexibility can be obtained. The content of the epoxy resin having a number average molecular weight of 600 or less in the resin components is 50% by weight or less, preferably 20% by weight or less, and more preferably 10% by weight or less. Because the content of the epoxy resin is 50% by weight or less, tack of the sheet can be suppressed, and the handling property improves.

The adhesive film for underfill of the present invention contains a phenol resin having a number average molecular weight exceeding 500. The number average molecular weight of the phenol resin is preferably 1,000 or more, and more preferably 1,200 or more. The upper limit of the number average molecular weight of the phenol resin is not especially limited; however, it is preferably 10,000 or less. If the number average molecular weight is 10,000 or less, the solubility in an organic solvent increases, and the productivity can be improved.

The hydroxyl equivalent weight of the phenol resin having a number average molecular weight exceeding 500 is not especially limited; however, it is preferably 200 g/eq or more. If the hydroxyl equivalent weight is 200 g/eq or more, the distance between crosslinking points becomes large, and the contraction caused by thermal curing can be suppressed to improve the thermal reliability of the semiconductor element. The upper limit of the hydroxyl equivalent weight is not especially limited; however, it is preferably 500 g/eq or less.

Examples of the phenol resin having a number average molecular weight exceeding 500 include a novolak phenol resin such as a phenol novolak resin, a phenol aralkyl resin, a cresol novolak resin, a tert-butylphenol novolak resin, and a nonylphenol novolak resin; a resol phenol resin; and polyoxystyrene such as polyparaoxystyrene. These may be used either alone or in combination of two or more thereof. Among these, a phenol aralkyl resin is preferable from a point of the thermal reliability, and a phenol aralkyl resin containing a skeleton represented by Formula (I) is more preferable.

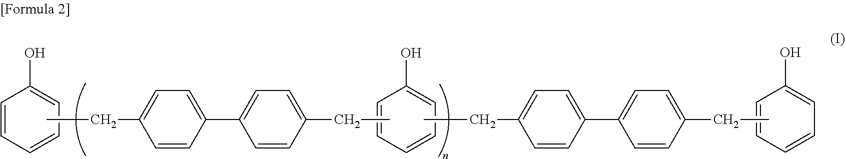

(In the formula, n represents an integer.)

The content of the phenol resin having a number average molecular weight exceeding 500 in the resin components is 5% by weight or more, preferably 10% by weight or more, and more preferably 20% by weight or more. Because the content of the phenol resin is 5% by weight or more, high thermal reliability can be obtained. The content of the phenol resin having a number average molecular weight exceeding 500 in the resin components is 50% by weight or less, and preferably 40% by weight or less. Because the content of the phenol resin is 50% by weight or less, good flexibility can be obtained.

The elastomer is not especially limited; however, an acrylic resin is preferable from a point of the electrical reliability and the heat resistance.

The acrylic resin is not particularly limited, and examples thereof include polymers having as a component one or more of esters of acrylic acids or methacrylic acids which have a linear or branched alkyl group having 30 or less of carbon atoms, especially 4 to 18 carbon atoms. Examples of the alkyl group include a methyl group, an ethyl group, a propyl group, an isopropyl group, an n-butyl group, a t-butyl group, an isobutyl group, an amyl group, an isoamyl group, a hexyl group, a heptyl group, a cyclohexyl group, a 2-ethylhexyl group, an octyl group, an isooctyl group, a nonyl group, an isononyl group, a decyl group, an isodecyl group, an undecyl group, a lauryl group, a tridecyl group, a tetradecyl group, a stearyl group, an octadecyl group, and an dodecyl group.

Other monomers for forming the polymer are not particularly limited, and examples thereof include cyano group-containing momomers such as acrylonitrile, carboxyl group-containing monomers such as acrylic acid, methacrylic acid, carboxyethyl acrylate, carboxypentyl acrylate, itaconic acid, maleic acid, fumaric acid, and crotonic acid, acid anhydride monomers such as maleic anhydride and itaconic anhydride, hydroxyl group-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxymethylcyclohexyl)-methyl acrylate, sulfonic acid group-containing monomers such as styrenesulfonic acid, allylsulfonic acid, 2-(meth)acrylamide-2-methylpropanesulfonic acid, (meth)acrylamidepropanesulfonic acid, sulfopropyl (meth)acrylate and (meth)acryloyloxynaphthalenesulfonic acid, and phosphoric acid group-containing monomers such as 2-hydroxyethylacryloyl phosphate.

The weight average molecular weight of the elastomer is not especially limited; however, it is preferably 100,000 or more, and more preferably 300,000 or more. If the weight average molecular weight is 100,000 or more, good flexibility can be imparted. The weight average molecular weight of the elastomer is preferably 800,000 or less, and more preferably 500,000 or less.

The content of the elastomer in the resin components is preferably 10% by weight or more, and more preferably 15% by weight or more. If the content of the elastomer is 10% by weight or more, good flexibility can be obtained. The content of the elastomer in the resin components is preferably 50% by weight or less, more preferably 40% by weight or less, and further preferably 35% by weight or less. If the content of the elastomer is 40% by weight or less, good thermal reliability can be obtained.

Other resin components may be compounded in addition to the epoxy resin having a number average molecular weight of 600 or less, the phenol resin having a number average molecular weight exceeding 500, and the elastomer. Examples of other resin components include an epoxy resin having a number average molecular weight exceeding 600 and a phenol resin having a number average molecular weight of 500 or less. Among these, an epoxy resin having a number average molecular weight of 1,000 or more is preferable. When the epoxy resin having a number average molecular weight of 1,000 or more, the physical property of the cured product improves, and the thermal reliability improves.

An epoxy resin having a number average molecular weight of 1,500 or more is preferable as the epoxy resin having a number average molecular weight of 1,000 or more. The upper limit of the number average molecular weight is not especially limited; however, it is preferably 10,000 or less. If the number average molecular weight is 10,000 or less, the solubility to an organic solvent improves, and the productivity can be improved.

The types of epoxy resin that are described as the examples of the epoxy resin having a number average molecular weight of 600 or less can be used as the epoxy resin having a number average molecular weight of 1,000 or more.

The content of the epoxy resin having a number average molecular weight of 1,000 or more in the resin components is preferably 10% by weight or more, and more preferably 20% by weight or more. Because the content of the epoxy resin is 10% by weight or more, the physical property of the cured product improves, and the thermal reliability improves. The content of the epoxy resin having a number average molecular weight of 1,000 or more in the resin components is preferably 40% by weight or less, and more preferably 30% by weight or less. Because the content of the epoxy resin is 40% by weight or less, the flexibility can be maintained.

The adhesive film for underfill of the present invention preferably contains a curing promoting catalyst. This makes it possible to promote curing of the epoxy resin (epoxy resin having a number average molecular weight of 600 or less, epoxy resin having a number average molecular weight exceeding 600, etc.) and the phenol resin (phenol resin having a number average molecular weight exceeding 500, phenol resin having a number average molecular weight of 500 or less, etc.) The curing promoting catalyst is not especially limited, and can be appropriately selected from known curing promoting catalysts and used. As the curing promoting catalyst, for example, an amine curing accelerator, a phosphorous curing accelerator, an imidazole curing accelerator, a boron curing accelerator, or a phosphorous-boron curing accelerator can be used. Among these, an imidazole curing accelerator is preferable, and 2-phenyl-4,5-dihydroxymethylimidazole and 2-phenyl-4-methy-5-hydroxymethylimidazole are more preferable.

The content of the curing promoting catalyst is preferably 0.1 parts by weight of the total content 100 parts by weight of the epoxy resin and the phenol resin. If the content is 0.1 parts by weight or more, the curing time by the heat treatment becomes small, and the productivity can be improved. The content of the curing promoting catalyst is preferably 5 parts by weight or less. If the content is 5 parts by weight or less, the preservability of the thermosetting resin can be improved.

The adhesive film for underfill of the present invention preferably contains an inorganic filler. This makes it possible to improve the heat resistance. Examples of the inorganic filler include powders of quartz glass, talc, silica (such as fused silica and crystalline silica), alumina, aluminum nitride, silicon nitride, and boron nitride. Among these, silica is preferable from the points of its excellent insulating property and small thermal expansion coefficient, and fused silica is more preferable.

The average particle size of the inorganic filler is preferably 0.01 μm or more, more preferably 0.05 μm or more, and further preferably 0.5 μm or more. If the average particle size is 0.01 μm or more, the effect of the surface area of the filler to the flexibility can be suppressed. The average particle size of the inorganic filler is preferably 10 μm or less, and more preferably 1 μm or less. If the average particle size is 10 μm or less, the inorganic filler can be satisfactorily filled in the gap between the semiconductor element and the substrate.

The average particles size is a value that is obtained by using an optical particle size analyzer (trade name; LA-910, manufactured by HORIBA, Ltd.)

The content of the inorganic filler in the adhesive film for underfill is preferably 30% by weight or more, and more preferably 35% by weight or more. If the content is 30% by weight or more, the viscosity of the film at high temperature can be adjusted in a preferable range. The content of the inorganic filler in the adhesive film for underfill is preferably 70% by weight or less, and more preferably 50% by weight or less. If the content is 70% by weight or less, good flexibility can be obtained, and the unevenness of the bump formation surface can be satisfactorily filled.

A flux may be added to the adhesive film for underfill of the present invention in order to remove the oxide film on the solder bump surface to ease mounting of the semiconductor element. The flux is not particularly limited, a previously known compound having a flux action can be used, and examples thereof include ortho-anisic acid, diphenolic acid, adipic acid, acetylsalicylic acid, benzoic acid, benzylic acid, azelaic acid, benzylbenzoic acid, malonic acid, 2,2-bis(hydroxymethyl)propionic acid, salicylic acid, o-methoxybenzoic acid, m-hydroxybenzoic acid, succinic acid, 2,6-dimethoxymethyl paracresol, hydrazide benzoate, carbohydrazide, dihydrazide malonate, dihydrazide succinate, dihydrazide glutarate, hydrazide salicylate, dihydrazide iminodiacetate, dihydrazide itaconate, trihydrazide citrate, thiocarbohydrazide, benzophenone hydrazone, 4,4′-oxybisbenzenesulfonyl hydrazide, dihydrazide adipate. The amount of the flux added may be any amount as long as the flux action can be exhibited, and it is normally about 0.1 to 20 parts by weight to 100 parts by weight of the resin components contained in the adhesive film for underfill.

The adhesive film for underfill of the present invention may be colored as necessary. The color that is given by coloring of the film is not especially limited; however, black, blue, red, green, etc., are preferable. A coloring agent can be used that is appropriately selected from known coloring agents such as a pigment and a dye.

When the adhesive film for underfill of the present invention is cross-linked to a certain extent in advance, it is possible to add a multifunctional compound that reacts with a functional group, etc., at the ends of the polymer molecular chain as a crosslinking agent in production. An example of the crosslinking agent includes a polyisocyanate compound such as tolylene diisocyanate, diphenylmethane diisocyanate, p-phenylene diisocyanate, 1,5-naphthalene diisocyanate, and an adduct of polyhydric alcohol and diisocyanate.

Other additives can be appropriately compounded in the adhesive film for underfill of the present invention as necessary. Examples of the other additives include a flame retardant, a silane coupling agent, and an ion trapping agent. Examples of the flame retardant include antimony trioxide, antimony pentoxide, and a brominated epoxy resin. Examples of the silane coupling agent include β-(3,4-epoxycyclohexyl)ethyltrimethoxysialne, γ-glycidoxypropyltrimethoxysilane, and γ-glycidoxypropylmethyldiethoxysilane. Examples of the ion trapping agent include hydrotalcites and bismuth hydroxide.

For example, the adhesive film for underfill of the present invention can be produced as follows. First, each of the components described above that are constituent materials of the adhesive film for underfill is compounded, and is dissolved or dispersed in a solvent (for example, methylethylketone or ethylacetate) to prepare a coating liquid. Next, the coating liquid prepared is applied onto a base separator to forma coating film having a prescribed thickness. Then, the coating film is dried to form an adhesive film for underfill.

The thickness of the adhesive film for underfill of the present invention may be appropriately set in consideration of the gap between the semiconductor element and the adherend or the height of the connection members. The thickness is preferably 10 to 100 μm.

When the viscosity of the adhesive film for underfill of the present invention is measured at 40 to 100° C., a temperature exists at which the viscosity becomes 20,000 Pa·s or less. If a temperature exists at which the viscosity becomes 20,000 Pa·s or less, the filling property of the film to the semiconductor element or the adherend improves, and a semiconductor element without voids can be obtained.

The temperature at which the viscosity becomes 20,000 Pa·s or less can be controlled by the content of the epoxy resin having a number average molecular weight of 600 or less, the content of the phenol resin having a number average molecular weight exceeding 500, the type of the elastomer, the content of the elastomer, the molecular weight of the elastomer, the content of the inorganic filler, etc.

The minimum viscosity of the adhesive film for underfill of the present invention at 100° C. to 200° C. is preferably 100 Pa·s or more, and more preferably 500 Pa·s or more. If the minimum viscosity is 100 Pas or more, the generation of voids due to outgas of the film can be suppressed. The upper limit of the minimum viscosity at 100 to 200° C. is not especially limited; however, it is preferably 10,000 Pa·s or less. If the upper limit is 10,000 Pa·s or less, the filling property of the film to the unevenness of the adherend improves.

The minimum viscosity at 100 to 200° C. can be controlled by the content of the epoxy resin having a number average molecular weight of 600 or less, the content of the phenol resin having a number average molecular weight exceeding 500, the content of the elastomer, the content of the inorganic filler, etc. For example, the content of the elastomer is increased or the content of the inorganic filler is increased to increase the minimum viscosity at 100 to 200° C.

The viscosity can be measured by using a rheometer. Specifically, the viscosity can be measured with the method described in the examples.

The adhesive film for underfill of the present invention is preferably protected by a separator. The separator has a function as a protecting material to protect the adhesive film for underfill before use. The separator is peeled off when the semiconductor element is pasted onto the adhesive film for underfill. Polyethylene terephthalate (PET), polyethylene, polypropylene, a plastic film, and a paper sheet in which its surface is coated with a peeling agent such as a fluorine peeling agent or a long-chain alkylacrylate peeling agent can be also used as a separator.

The space between the semiconductor element and the adherend is filled with the adhesive film for underfill of the present invention to protect a connection part of the connection members of the semiconductor element and the electrically conductive material of the adherend. Examples of the semiconductor element include a semiconductor wafer, a semiconductor chip, and a semiconductor package. Examples of the adherend include a wired circuit board, a flexible board, an interposer, a semiconductor wafer, and a semiconductor element. Examples of the material of the connection members include solders (alloys) such as tin-lead metal, tin-silver metal, tin-silver-copper metal, tin-zinc metal, and tin-zinc-bismuth metal; gold metal; and copper metal. The material of the electrically conductive members is not especially limited as long as the material is electrically conductive, and includes, for example, copper.

The adhesive film for underfill of the present invention can be integrally used with a tape for grinding a rear surface or a dicing tape. This makes it possible to manufacture a semiconductor device effectively.

[Adhesive Film for Underfill Integrated with a Tape for Grinding Rear Surface]

The adhesive film for underfill integrated with a tape for grinding a rear surface of the present invention has the tape for grinding the rear surface and the adhesive film for underfill.

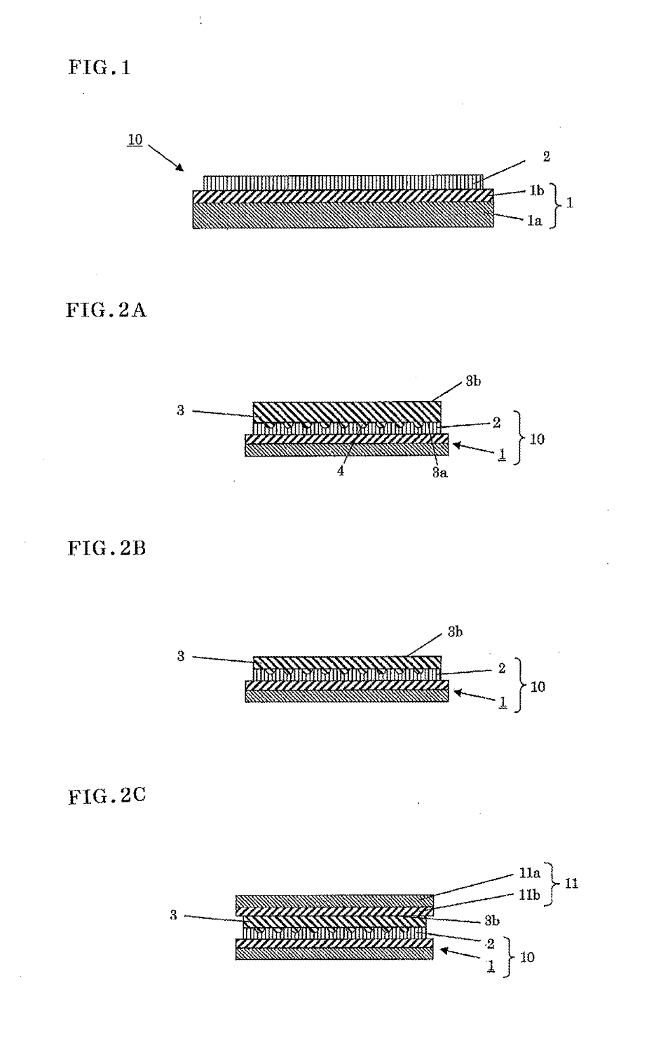

FIG. 1 is a schematic cross sectional view of an adhesive film 10 for underfill integrated with a tape for grinding the rear surface. As shown in FIG. 1, the adhesive film 10 for underfill integrated with the tape for grinding the rear surface includes a tape 1 for grinding the rear surface and an adhesive film 2 for underfill. The tape 1 for grinding the rear surface includes a base 1a and a pressure-sensitive adhesive layer 1b, and the pressure-sensitive adhesive layer 1b is provided on the base 1a. The underfill film 2 is provided on the pressure-sensitive adhesive layer 1b.

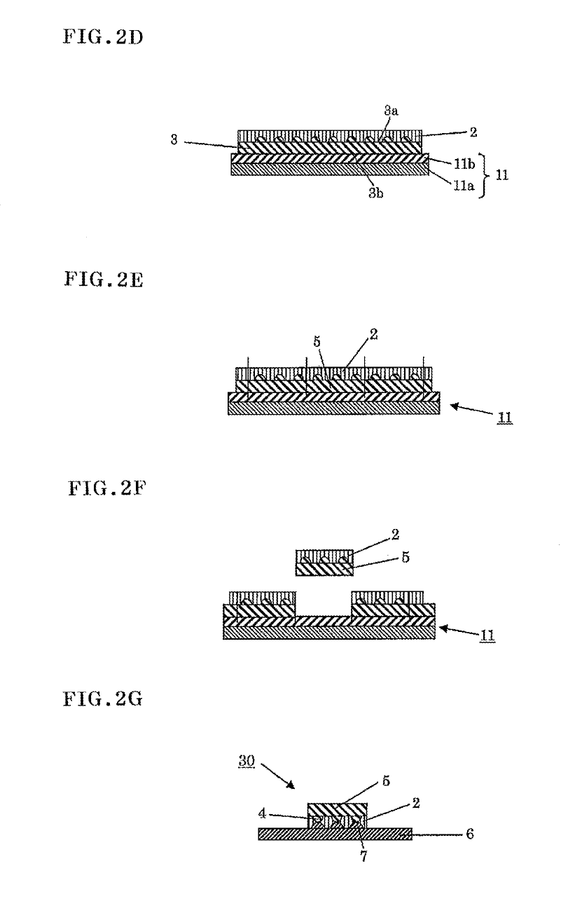

The adhesive film 2 for underfill may not be laminated on the entire surface of the tape 1 for grinding the rear surface as shown in FIG. 1, and it is satisfactory if the adhesive film 2 for underfill is provided to a size that is sufficient for pasting with semiconductor wafer 3 (refer to FIG. 2A).

(Tape for Grinding Rear Surface)

The tape 1 for grinding the rear surface includes the base 1a and the pressure-sensitive adhesive layer 1b that is laminated on the base 1a.

The base 1a becomes a base material for strength of the adhesive film 10 for underfill integrated with the tape for grinding the rear surface. Examples include polyolefins such as low-density polyethylene, linear polyethylene, medium-density polyethylene, high-density polyethylene, very low-density polyethylene, random copolymerized polypropylene, block copolymerized polypropylene, homo polypropylene, polybutene, and polymethylpentene, an ethylene-vinyl acetate copolymer, an ionomer resin, an ethylene-(meth)acrylic acid copolymer, an ethylene-(meth)acrylate (random, alternating) copolymer, an ethylene-butene copolymer, an ethylene-hexene copolymer, polyurethane, polyesters such as polyethylene terephthalate, and polyethylene naphthalate, polycarbonate, polyimide, polyether ether ketone, polyimide, polyetherimide, polyamide, total aromatic polyamide, polyphenyl sulfide, alamid (paper), glass, glass cloth, a fluororesin, polyvinyl chloride, polyvinylidene chloride, a cellulose-based resin, a silicone resin, a metal (foil), and papers such as glassine paper. When the pressure-sensitive adhesive layer 1b is of an ultraviolet-ray curing type, the base 1a is preferably one having a permeability to ultraviolet rays.

For the base 1a, the same material or different material can be appropriately selected and used, and one obtained by blending several materials can be used as necessary. A traditional surface treatment can be performed on the surface of the base 1a. The base 1a can include a vapor-deposited layer of an electrically conductive substance made of a metal, an alloy, an oxide thereof, etc., and having a thickness of about 30 to 500 angstroms for imparting an antistatic property. The base 1a may be a single layer or a multiple layer having two or more layers.

The thickness of the base 1a can be appropriately determined, but is generally about 5 μm or more and 200 μm or less, and preferably about 35 μm or more and 120 μm or less.

The base 1a may contain various kinds of additives (e.g. colorant, filler, plasticizer, antiaging agent, antioxidant, surfactant, flame retardant, etc.)

A pressure-sensitive adhesive used for forming the pressure-sensitive adhesive layer 1b is not particularly limited as long as it can hold a semiconductor wafer while grinding the rear surface of a semiconductor wafer and can be peeled from the semiconductor wafer after grinding the rear surface. For example, a general pressure-sensitive adhesive can be used such as an acrylic pressure-sensitive adhesive and a rubber pressure-sensitive adhesive. As the pressure-sensitive adhesive, an acrylic pressure-sensitive adhesive having an acrylic polymer as a base polymer is preferable from points of the cleaning and washing properties of an electronic component such as a semiconductor wafer and a glass that is required to be free from contamination by using ultrapure water or an organic solvent such as alcohol.

Examples of the acryl-based polymer include those using an acrylate as a main monomer component. Examples of the acrylate include one or more of (meth)acrylic acid alkyl esters (for example, linear or branched alkyl esters with the alkyl group having 1 to 30, particularly 4 to 18 carbon atoms, such as methyl ester, ethyl ester, propyl ester, isopropyl ester, butyl ester, isobutyl ester, s-butyl ester, t-butyl ester, pentyl ester, isopentyl ester, hexyl ester, heptyl ester, octyl ester, 2-ethylhexyl ester, isooctyl ester, nony ester, decyl ester, isodecyl ester, undecyl ester, dodecyl ester, tridecyl ester, tetradecyl ester, hexadecyl ester, octadecyl ester and eicosyl ester), and (meth)acrylic acid cycloalkyl esters (for example, cyclopentyl ester and cyclohexyl ester, etc.). The (meth)acrylic acid ester refers to an acrylic acid ester and/or a methacrylic acid ester, and (meth) has the same meaning throughout the present invention.

The acryl-based polymer may contain a unit corresponding to any other monomer component capable of being copolymerized with the (meth) acrylic acid alkyl ester or cycloalkyl ester as necessary for the purpose of modifying cohesive strength, heat resistance, and so on. Examples of the monomer component include carboxyl group-containing monomers such as acrylic acid, methacrylic acid, carboxyethyl (meth)acrylate, carboxypentyl (meth)acrylate, itaconic acid, maleic acid, fumaric acid, and crotonic acid; acid anhydride monomers such as maleic anhydride and itaconic anhydride; hydroxyl group-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxymethylcyclohexyl)-methyl (meth)acrylate; sulfonic acid group-containing monomers such as styrenesulfonic acid, allylsulfonic acid, 2-(meth)acrylamide-2-methylpropanesulfonic acid, (meth)acrylamidepropanesulfonic acid, sulfopropyl (meth)acrylate, and (meth)acryloyloxynaphthalenesulfonic acid; phosphoric acid group-containing monomers such as 2-hydroxyethylacryloyl phosphate; and acrylamide and acrylonitrile. One or more of these monomers capable of being copolymerized can be used. The used amount of the monomer component capable of copolymerization is preferably 40% by weight or less based on total monomer components.

Further, the acryl-based polymer may contain a polyfunctional monomer or the like as a monomer component for copolymerization as necessary for the purpose of crosslinking. Examples of the polyfunctional monomer include hexanediol di(meth)acrylate, (poly)ethylene glycol di(meth)acrylate, (poly)propylene glycol di(meth)acrylate, neopentylglycol di(meth)acrylate, pentaerythrithol di(meth)acrylate, trimethylolpropane tri(meth)acrylate, pentaerythrithol tri(meth)acrylate, dipentaerythrithol hexa(meth)acrylate, epoxy (meth)acrylate, polyester (meth)acrylate, and urethane (meth)acrylate. One or more of these polyfunctional monomers can be used. The used amount of the polyfunctional monomer is preferably 30% by weight or less based on total monomer components from the viewpoint of an adhesion property.

The acryl-based polymer is obtained by subjecting a single monomer or monomer mixture of two or more kinds of monomers to polymerization. Polymerization can be carried out by any method such as solution polymerization, emulsion polymerization, bulk polymerization, or suspension polymerization. The content of low-molecular weight substances is preferably low from the viewpoint of prevention of contamination of a clean adherend. In this respect, the number average molecular weight of the acryl-based polymer is preferably 300,000 or more, further preferably about 400,000 to 3,000,000.

For the pressure-sensitive adhesive, an external cross-linker can also be appropriately employed for increasing the number average molecular weight of an acryl-based polymer or the like as a base polymer. Specific examples of the external crosslinking methods include a method in which so called a cross-linker such as a polyisocyanate compound, an epoxy compound, an aziridine compound, or a melamine-based cross-linker is added and reacted. When an external cross-linker is used, the used amount thereof is appropriately determined according to a balance with a base polymer to be crosslinked, and further a use application as a pressure-sensitive adhesive. Generally, the external cross-linker is blended in an amount of preferably about 5 parts by weight or less, further preferably 0.1 to 5 parts by weight, based on 100 parts by weight of the base polymer. Further, for the pressure-sensitive adhesive, previously known various kinds of additives, such as a tackifier and an anti-aging agent, may be used as necessary in addition to the aforementioned components.

The pressure-sensitive adhesive layer 1b can be formed from a radiation curing-type pressure-sensitive adhesive. By irradiating the radiation curing-type pressure-sensitive adhesive with radiations such as ultraviolet rays, the degree of crosslinking thereof can be increased to easily reduce its adhesive power, so that pickup can be easily performed. Examples of radiations include X-rays, ultraviolet rays, electron rays, α rays, β rays, and neutron rays.

For the radiation curing-type pressure-sensitive adhesive, one having a radiation-curable functional group such as a carbon-carbon double bond and showing adherability can be used without particular limitation. Examples of the radiation curing-type pressure-sensitive adhesive may include, for example, an addition-type radiation-curable pressure-sensitive adhesive obtained by blending a radiation-curable monomer component or an oligomer component with a general pressure-sensitive adhesive such as the above-mentioned acryl-based pressure-sensitive adhesive or rubber-based pressure-sensitive adhesive.

Examples of the radiation curable monomer component to be blended include urethane oligomer, urethane (meth)acrylate, trimethylolpropane tri(meth)acrylate, tetramethylolmethane tetra(meth)acrylate, pentaerythrithol tri(meth)acrylate, pentaerythrithol tetra(meth)acrylate, dipentaerythrithol monohydroxypenta(meth)acrylate, dipentaerythrithol hexa(meth)acrylate, and 1,4-butanediol di(meth)acrylate. Examples of the radiation curable oligomer component include various oligomers such as urethane-based, polyether-based, polyester-based, polycarbonate-based and polybutadiene-based oligomers, and the appropriate weight-average molecular weight thereof is in a range of about 100 to 30,000. For the blending amount of the radiation curable monomer component or oligomer component, an amount allowing the adhesive strength of the pressure-sensitive adhesive layer to be reduced can be appropriately determined according to the type of the pressure-sensitive adhesive layer. Generally, the blending amount is, for example, 5 to 500 parts by weight, preferably about 40 to 150 parts by weight, based on 100 parts by weight of a base polymer such as an acryl-based polymer forming the pressure-sensitive adhesive.

Examples of the radiation curing-type pressure-sensitive adhesive include, besides the addition-type radiation curing-type pressure-sensitive adhesive described previously, an intrinsic radiation curing-type pressure-sensitive adhesive using, as a base polymer, a polymer having a carbon-carbon double bond in the polymer side chain or main chain or at the end of the main chain. The intrinsic radiation curing-type pressure-sensitive adhesive is preferable because it is not required to contain, or mostly does not contain, an oligomer component or the like which is a low-molecular component, and therefore the oligomer component or the like does not migrate in the pressure-sensitive adhesive over time, so that a pressure-sensitive adhesive layer having a stable layer structure can be formed.

For the base polymer having a carbon-carbon double bond, one having a carbon-carbon double bond and also an adherability can be used with no particular limitation. Such abase polymer is preferably one having an acryl-based polymer as a basic backbone. Examples of the basic backbone of the acryl-based polymer include the acryl-based polymers described previously as an example.

The method for introducing a carbon-carbon double bond into the acryl-based polymer is not particularly limited, and various methods can be employed, but it is easy in molecular design to introduce the carbon-carbon double bond into a polymer side chain. Mention is made to, for example, a method in which a monomer having a functional group is copolymerized into an acryl-based polymer beforehand, and thereafter a compound having a functional group that can react with the above-mentioned functional group, and a carbon-carbon double bond is subjected to a condensation or addition reaction while maintaining the radiation curability of the carbon-carbon double bond.

Examples of the combination of these functional groups include a combination of a carboxylic acid group and an epoxy group, a combination of a carboxylic acid group and an aziridyl group and a combination of a hydroxyl group and an isocyanate group. Among these combinations of functional groups, the combination of a hydroxyl group and an isocyanate group is suitable in terms of ease of reaction tracing. The functional group may be present at the side of any of the acryl-based polymer and the aforementioned compound as long as the combination of the functional groups is such a combination that the acryl-based polymer having a carbon-carbon double bond is generated, but for the preferable combination, it is preferred that the acryl-based polymer have a hydroxyl group and the aforementioned compound have an isocyanate group. In this case, examples of the isocyanate compound having a carbon-carbon double bond include metacryloyl isocyanate, 2-metacryloyloxyethyl isocyanate, m-isopropenyl-α, and α-dimethylbenzyl isocyanate. As the acryl-based polymer, one obtained by copolymerizing the hydroxy group-containing monomers described previously as an example, ether-based compounds such as 2-hydroxyethy lvinyl ether, 4-hydroxybutyl vinyl ether and diethylene glycol monovinyl ether, and so on, is used.

For the intrinsic radiation curing-type pressure-sensitive adhesive, the base polymer (particularly acryl-based polymer) having a carbon-carbon double bond can be used alone, but the radiation curable monomer component or oligomer component can also be blended, within the bounds of not deteriorating properties. The amount of the radiation curable oligomer component or the like is normally within a range of 30 parts by weight or less, preferably in a range of 0 to 10 parts by weight, based on 100 parts by weight of the base polymer.

A photopolymerization initiator is preferably included in the radiation curing-type pressure-sensitive adhesive when it is cured by ultraviolet rays or the like. Examples of the photopolymerization initiator include α-ketol-based compounds such as 4-(2-hydroxyethoxy)phenyl(2-hydroxy-2-propyl)ketone, α-hydroxy-α,α′-dimethylacetophenone, 2-methyl-2-hydroxypropiophenone, and 1-hydroxycyclohexyl phenyl ketone; acetophenone-based compounds such as methoxyacetophenone, 2,2-dimethoxy-2-phenylacetophenone, 2,2-diethoxyacetophenone, and 2-methyl-1-[4-(methylthio)-phenyl]-2-morphorinopropane-1; benzoin ether-based compounds such as benzoin ethyl ether, benzoin isopropyl ether, and anisoin methyl ether; ketal-based compounds such as benzyldimethylketal; aromatic sulfonyl chloride-based compounds such as 2-naphthalenesulfonyl chloride; photoactive oxime-based compounds such as 1-phenone-1,1-propanedione-2-(o-ethoxycarbonyl)oxime; benzophenone-based compounds such as benzophenone, benzoyl benzoic acid, and 3,3′-dimethyl-4-methoxybenzophenone; thioxanthone-based compounds such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketone; acylphosphinoxide; and acylphosphonate. The blending amount of the photopolymerization initiator is, for example, about 0.05 to 20 parts by weight based on 100 parts by weight of the base polymer such as an acryl-based polymer which forms a pressure-sensitive adhesive.

When curing hindrance by oxygen occurs at the time of the irradiation, it is desirable to block oxygen (air) from the surface of the radiation curing-type pressure-sensitive adhesive layer 1b by some method. Examples include a method in which the surface of the pressure-sensitive adhesive layer 1b is covered with a separator, and a method in which irradiation such as with ultraviolet rays or the like is carried out in a nitrogen gas atmosphere.

The pressure-sensitive adhesive layer 1b may contain various kinds of additives (e.g. colorant, thickener, bulking agent, filler, tackifier, plasticizer, antiaging agent, antioxidant, surfactant, crosslinking agent, etc.)

The thickness of the pressure-sensitive adhesive layer 1b is not particularly limited; however, it is preferably about 1 to 50 μm from the viewpoints of preventing chipping of a chip cut surface, compatibility of fixing and maintaining the adhesive film 2 for underfill, etc. The thickness is preferably 2 to 30 μm, and more preferably 5 to 25 μm.

(Method of Manufacturing Adhesive Film for Underfill Integrated with Tape for Grinding Rear Surface)

For example, the tape 1 for grinding the rear surface and the adhesive film 2 for underfill are separately produced and they are finally pasted to each other to make the adhesive film 10 for underfill integrated with a tape for grinding the rear surface.

(Method of Manufacturing Semiconductor Device Using Adhesive Film for Underfill Integrated with Tape for Grinding Rear Surface)

Next, a method of manufacturing a semiconductor device using the adhesive film 10 for underfill integrated with a tape for grinding the rear surface will be described. Each of FIGS. 2A to 2G is a view showing each step of the method of manufacturing a semiconductor device using the adhesive film 10 for underfill integrated with a tape for grinding the rear surface.

Specifically, the method of manufacturing a semiconductor device includes the following steps: a pasting step of pasting a circuit surface 3a on which connection members 4 of the semiconductor wafer 3 are formed to the adhesive film 2 for underfill of the adhesive film 10 for underfill integrated with a tape for grinding the rear surface; a grinding step of grinding a rear surface 3b of the semiconductor wafer 3; a fixing step of pasting a dicing tape 11 to a rear surface 3b of the semiconductor wafer 3; a peeling step of peeling the tape 1 for grinding the rear surface; a dicing step of dicing the semiconductor wafer 3 to form a semiconductor chip 5 with the adhesive film 2 for underfill; a pickup step of peeling the semiconductor chip 5 with the adhesive film 2 for underfill from the dicing tape 11; a connecting step of electrically connecting the semiconductor chip 5 and an adherend 6 through the connection member 4 while filling the space between the semiconductor chip 5 and the adherend 6 with the adhesive film 2 for underfill; and a curing step of curing the adhesive film 2 for underfill.

<Pasting Step>

In the pasting step, the circuit surface 3a on which the connection members 4 of the semiconductor wafer 3 are formed is pasted to the adhesive film 2 for underfill of the adhesive film 10 for underfill integrated with a tape for grinding the rear surface (refer to FIG. 2A).

A plurality of the connection members 4 are formed on the circuit surface 3a of the semiconductor wafer 3 (refer to FIG. 2A). The height of the connection member 4 is determined depending on its use, and it is generally about 15 to 100 μm. Naturally, the height of each connection member 4 in the semiconductor wafer 3 may be the same or different from each other.

A height X (μm) of the connection member 4 that is formed on the surface of the semiconductor wafer 3 and a thickness Y (μm) of the adhesive film 2 for underfill preferably satisfy the following relationship:

0.5≦Y/X≦2.

When the height X (μm) of the connection member 4 and the thickness Y (μm) of the adhesive film 2 for underfill satisfy the above relationship, the space between the semiconductor chip 5 and the adherend 6 can be sufficiently filled, excess flow-out of the adhesive film 2 for underfill from the space can be prevented, and contamination, etc., of the semiconductor chip 5 by the adhesive film 2 for underfill can be prevented. When the height of each connection member 4 is different from each other, the largest height of the connection member 4 is set as a standard.

First, a separator that is arbitrarily provided on the adhesive film 2 for underfill of the adhesive film 10 for underfill integrated with a tape for grinding the rear surface is appropriately peeled, and the circuit surface 3a on which the connection members 4 of the semiconductor wafer 3 are formed is arranged to face the adhesive film 2 for underfill as shown in FIG. 2A, so that the adhesive film 2 for underfill and the semiconductor wafer 3 are pasted together (mounting).

The method of the pasting is not especially limited; however, a method of press-bonding is preferable. The pressure of press-bonding is preferably 0.1 MPa or more, and more preferably 0.2 MPa or more. If the pressure is 0.1 MPa or more, the unevenness of the circuit surface 3a of the semiconductor wafer 3 can be suitably filled. The upper limit of the pressure of press-bonding is not especially limited; however, it is preferably 1 MPa or less, and more preferably 0.5 MPa or less.

The temperature at the pasting is preferably 60° C. or higher, and more preferably 70° C. or higher. If the temperature is 60° C. or higher, the viscosity of the adhesive film 2 for underfill decreases, and the adhesive film 2 for underfill can fill the unevenness of the semiconductor wafer 3 without any gap. The temperature at the pasting is preferably 100° C. or lower, and more preferably 80° C. or lower. If the temperature is 100° C. or lower, the pasting can be performed while suppressing the curing reaction of the adhesive film 2 for underfill.

The pasting is preferably performed under reduced pressure, for example, 1,000 Pa or less, and preferably 500 Pa or less. The lower limit is not especially limited, and for example, 1 Pa or more.

<Grinding Step>

In the grinding step, the surface opposite to the circuit surface 3a of the semiconductor wafer 3 (that is, the rear surface), 3b, is ground (refer to FIG. 2B). A thin-type processing apparatus that is used in grinding the rear surface of the semiconductor wafer 3 is not especially limited, and examples thereof include a grinding apparatus (back grinder) and a polishing pad. The rear surface may be ground with a chemical method such as etching. The rear surface is ground until the thickness of the semiconductor wafer 3 reaches a desired thickness (for example, 700 to 25 μm).

<Wafer Fixing Step>

After the grinding step, the dicing tape 11 is pasted to the rear surface 3b of the semiconductor wafer 3 (refer to FIG. 2C). The dicing tape 11 has a structure in which a pressure-sensitive adhesive layer 11b is laminated on a base 11a. The base 11a and the pressure-sensitive adhesive layer 11b can be suitably produced using the components and the manufacturing method shown in the section of the base 1a and pressure-sensitive adhesive layer 1b of the tape 1 for grinding the rear surface.

<Peeling Step>

Next, the tape 1 for grinding the rear surface is peeled (refer to FIG. 2D). This allows the adhesive film 2 for underfill to be exposed.

When the pressure-sensitive adhesive layer 1b is radiation curable, the pressure-sensitive adhesive layer 1b is cured by irradiating the layer 1b with radiation to easily peel the tape 1 for grinding the rear surface. The amount of radiation may be appropriately set in consideration of the type of radiation to be used, the degree of curing of the pressure-sensitive adhesive layer, etc.

<Dicing Step>

In the dicing step, the semiconductor wafer 3 and the adhesive film 2 for underfill are diced to form the semiconductor chip 5 with the adhesive film 2 for underfill as shown in FIG. 2E. The dicing is performed from the circuit surface 3a to which the adhesive film 2 for underfill of the semiconductor wafer 3 is pasted with a normal method. An example includes a cutting method called “full cut” in which cutting is performed up to the dicing tape 11. The dicing apparatus that is used in this step is not especially limited, and a conventionally known apparatus can be used.

When the expansion of the dicing tape 11 is performed successively after the dicing step, the expansion can be performed by using a conventionally known expanding apparatus.

<Pickup Step>

As shown in FIG. 2F, the semiconductor chip 5 with the adhesive film 2 for underfill is peeled from the dicing tape 11 (the semiconductor chip 5 with the adhesive film. 2 for underfill is picked up). The pickup method is not especially limited, and various types of conventionally known methods can be adopted.

When the pressure-sensitive adhesive layer 11b of the dicing tape 11 is ultraviolet curable, the pickup is performed after irradiating the pressure-sensitive adhesive layer 11b with ultraviolet rays. This allows the adhesive strength of the pressure-sensitive adhesive layer 11b to the semiconductor chip 5 to be decreased, and makes peeling of the semiconductor chip 5 easy.

<Connecting Step>

In the connecting step, the semiconductor chip 5 and the adherend 6 are electrically connected to each other through the connection member 4 while filling the space between the adherend 6 and the semiconductor chip 5 with the adhesive film 2 for underfill (refer to FIG. 2G). Specifically, the connection member 4 that is formed on the semiconductor chip 5 is brought into contact with an electrically conductive material 7 for bonding that is attached to the connection pad of the adherend 6, and the electrically conductive material 7 is melted while pressing the connection member 4 to electrically connect the semiconductor chip 5 to the adherend 6. Since the adhesive film 2 for underfill is pasted to the circuit surface 3a of the semiconductor chip 5, the semiconductor chip 5 and the adherend 6 are electrically connected to each other, and the space between the semiconductor chip 5 and the adherend 6 is filled with the adhesive film 2 for underfill.

The heating conditions in the connecting step are not especially limited; however, the temperature is normally 100 to 300° C., and the pressure applied is normally 0.5 to 500 N.

The heat press-bonding process in the connecting step may be performed in multiple stages. When the heat press-bonding process is performed in multiple stages, the resin between the connection member 4 and the electrically conductive material 7 can be effectively removed, and better connection between metals can be obtained.

<Curing Step>

After the semiconductor chip 5 and the adherend 6 are electrically connected to each other, the adhesive film 2 for underfill is cured by heating. This makes it possible to secure the connection reliability between the semiconductor chip 5 and the adherend 6. The heating temperature for curing the adhesive film 2 for underfill is not especially limited, and for example, it is 150 to 200° C. for 10 to 120 minutes. The adhesive film for underfill may be cured by the heating process in the connecting step.

<Sealing Step>

Next, a sealing step may be performed for protecting an entire semiconductor device 30 including the mounted semiconductor chip 5. The sealing step is performed by using a sealing resin. The sealing conditions are not especially limited, and heating is normally performed at 175° C. for 60 seconds to 90 seconds to thermally cure the sealing resin. However, the present invention is not limited to this. For example, the curing can be performed at 165° C. to 185° C. for a few minutes.

A resin having an insulating property (an insulating resin) is preferable as the sealing resin, and the sealing resin can be appropriately selected from known sealing resins for use.

<Semiconductor Device>

In the semiconductor device 30, the semiconductor chip 5 and the adherend 6 are electrically connected to each other through the connection member 4 that is formed on the semiconductor chip 5 and the electrically conductive material 7 that is provided on the adherend 6. The adhesive film 2 for underfill is arranged between the semiconductor chip 5 and the adherend 6 so that the film fills the space.

[Adhesive Film for Underfill Integrated with Dicing Tape]

The adhesive film for underfill integrated with dicing tape of the present invention includes a dicing tape and the adhesive film for underfill.

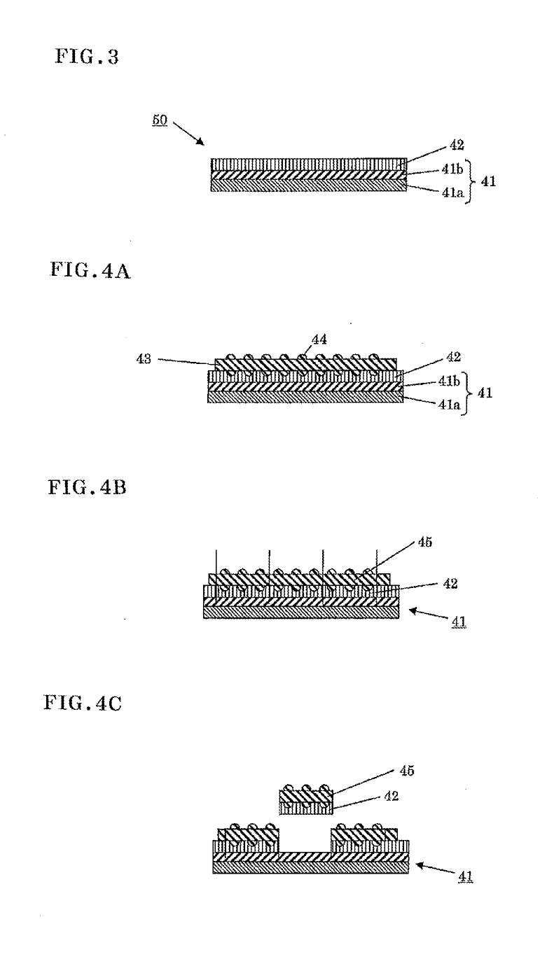

FIG. 3 is a schematic cross sectional view of an adhesive film 50 for underfill integrated with a dicing tape. As shown in FIG. 3, the adhesive film 50 for underfill integrated with a dicing tape includes a dicing tape 41 and an adhesive film 42 for underfill.

The dicing tape 41 includes a base 41a and a pressure-sensitive adhesive layer 41b, and the pressure-sensitive adhesive layer 41b is provided on the base 41a. The adhesive film 42 for underfill is provided on the pressure-sensitive adhesive layer 41b.

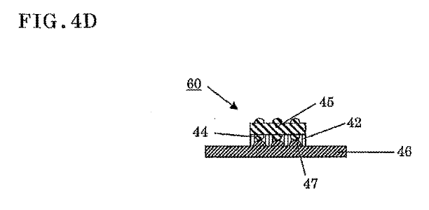

The adhesive film 42 for underfill may not be laminated on the entire surface of the dicing tape 41 as shown in FIG. 3, and it is satisfactory if the adhesive film 42 for underfill is provided to a size that is sufficient for pasting with a semiconductor wafer 43 (refer to FIG. 4A).

The dicing tape 41 includes the base 41a and the pressure-sensitive adhesive layer 41b that is laminated on the base 41a. As the base 41a, examples described herein of base 1a can be used. As the pressure-sensitive adhesive layer 41b, examples described herein of pressure-sensitive adhesive layer 1b can be used.

(Method of Manufacturing Semiconductor Device Using Adhesive Film for Underfill Integrated with Dicing Tape)

Next, a method of manufacturing a semiconductor device using the adhesive film 50 for underfill integrated with a dicing tape will be described. Each of FIGS. 4A to 4D is a view showing a step of the method of manufacturing a semiconductor device using the adhesive film 50 for underfill integrated with a dicing tape. Specifically, the method of manufacturing a semiconductor device includes the following steps: a pasting step of pasting the semiconductor wafer 43 on both surfaces of which a circuit surface having connection members 44 are formed, to the adhesive film 42 for underfill of the adhesive film 50 for underfill integrated with a dicing tape; a dicing step of dicing the semiconductor wafer 43 to form a semiconductor chip 45 with the adhesive film 42 for underfill; a pickup step of peeling the semiconductor chip 45 with the adhesive film 42 for underfill from the dicing tape 41; a connecting step of electrically connecting the semiconductor chip 45 and an adherend 46 through the connection member 44 while filling the space between the semiconductor chip 45 and the adherend 46 with the adhesive film 42 for underfill; and a curing step of curing the adhesive film 42 for underfill.

<Pasting Step>

In the pasting step, the semiconductor wafer 43 on both surfaces of which a circuit surface having connection members 44 are formed is pasted to the adhesive film 42 for underfill of the adhesive film 50 for underfill integrated with a dicing tape as shown in FIG. 4A. The semiconductor wafer 43 is normally weak in strength, so that the semiconductor wafer 43 may be fixed to a support such as support glass for reinforcement (not shown). In this case, a step of peeling the support may be included after pasting the semiconductor wafer 43 to the adhesive film 42 for underfill. When any one of the circuit surfaces of the semiconductor wafer 43 is pasted to the adhesive film 42 for underfill, the combination to be pasted may be changed depending on the structure of a desired semiconductor device.

The connection members 44 on both surfaces of the semiconductor wafer 43 may be or may not be electrically connected to each other. An example of the electric connection of the connection members 44 includes a connection through a via, which is called a TSV method. The pasting conditions described in the step of pasting the adhesive film 10 for underfill integrated with a tape for grinding the rear surface can be adopted as the pasting conditions.

<Dicing Step>

In the dicing step, the semiconductor wafer 43 and the adhesive film 42 for underfill are diced to form the semiconductor chip 45 with the adhesive film 42 for underfill (refer to FIG. 4B). The dicing conditions described in the step of dicing the adhesive film 10 for underfill integrated with a tape for grinding the rear surface can be adopted as the dicing conditions.

<Pickup Step>

In the pickup step, the semiconductor chip 45 with the adhesive film 42 for underfill is peeled from the dicing tape 41 (FIG. 4C).

The pickup conditions described in the step of picking up the adhesive film 10 for underfill integrated with a tape for grinding the rear surface can be adopted as the pickup conditions.

<Connecting Step>

In the connecting step, the semiconductor chip 45 and the adherend 46 are electrically connected to each other through the connection member 44 while filling the space between the semiconductor chip 45 and the adherend 46 with the adhesive film 42 for underfill (refer to FIG. 4D). A specific connection method is the same as the contents described in the connecting step of the adhesive film 10 for underfill integrated with a tape for grinding the rear surface. The heating conditions in the connecting step are the same as the heating conditions of the adhesive film 10 for underfill integrated with a tape for grinding the rear surface described above.

<Curing Step and Sealing Step>

The curing step and the sealing step are the same as the contents described in the curing step and the sealing step of the adhesive film 10 for underfill integrated with a tape for grinding the rear surface. This makes it possible to manufacture a semiconductor device 60.

### EXAMPLES

The preferred working examples of this invention will be explained in detail below. However, the materials, the compounding amounts, etc., described in the working examples are not intended to be limited thereto in the scope of this invention unless otherwise specified.

Each of the components used in the examples and the comparative examples will be summarized below.

Acrylic resin: trade name “Paracron W-197CM” manufactured by Negami Chemical Industrial Co., Ltd. (acrylic ester polymer containing ethylacrylate-methylmethacrylate as main component, M_{w}: 400,000)

Epoxy resin 1: trade name “jER1004” manufactured by Mitsubishi Chemical Corporation (bisphenol A epoxy resin, Mₙ: 1,650, epoxy equivalent weight: 875 to 975 g/eq)

Epoxy resin 2: trade name “jER828” manufactured by Mitsubishi Chemical Corporation (bisphenol A epoxy resin, Mₙ: 370, epoxy equivalent weight: 184 to 194 g/eq)

Phenol resin 1: trade name “MEH-7851SS” manufactured by MEIWA PLASTIC INDUSTRIES, LTD. (resin containing a skeleton shown in Formula (I), Mₙ: 550, hydroxyl equivalent weight: 202 g/eq)

Phenol resin 2: trade name “MEH-7851-4H” manufactured by MEIWA PLASTIC INDUSTRIES, LTD. (Resin containing a skeleton shown in Formula (I), Mₙ: 1,230, hydroxyl equivalent weight: 242 g/eq)

Phenol resin 3: trade name “MEH-7500” manufactured by MEIWA PLASTIC INDUSTRIES, LTD. (triphenylmethane phenol resin, Mₙ: 490, hydroxyl equivalent weight: 97 g/eq)

Silica filler: Spherical silica (trade name “SO-25R”, average particle size: 500 nm (0.5 μm), manufactured by Admatechs)

Organic acid: ortho-anisic acid manufactured by Tokyo Chemical Industry Co., Ltd.

Imidazole catalyst: trade name “2PHZ-PW” manufactured by Shikoku Chemicals Corporation (2-phenyl-4,5-dihydroxymethylimidazole)

[Production of Adhesive Film]

The components described above were dissolved in methylethylketone at the proportions shown in Table 1 to prepare solutions of adhesive compositions each of which has a solid concentration of 23.6% by weight.

Each of the solutions of the adhesive compositions was applied onto a release-treated film of a silicone release-treated polyethylene terephthalate film having a thickness of 50 μm, and the resultant was dried at 130° C. for 2 minutes to produce an adhesive film having a thickness of 45 μm.

The following evaluations were performed on the obtained adhesive film. The results are shown in Table 1.

[Flexibility]

A slit of 3 m in length and 330 mm in width was made into the adhesive film having a thickness of 45 μm, and the adhesive film was wrapped around a polypropylene winding core having a diameter of 3 inches. The case in which cracking did not occur in the adhesive film was evaluated as “◯”, and the case in which cracking occurred in the adhesive film was evaluated as “x”.

[Glass Transition Temperature (T_{g})]

First, the adhesive film was thermally cured by heating treatment at 175° C. for 1 hour. Thereafter, the adhesive film was cut into a rectangular shape of 200 μm in thickness, 40 mm in length (measurement length) and 10 mm in width, and the storage modulus and the loss modulus at −50 to 300° C. were measured by using a solid viscoelasticity measurement apparatus (RSA-III manufactured by Rheometric Scientific, Inc.) The measurement conditions were as follows; a frequency of 1 Hz and a rising temperature speed of 10° C./min. A value of tan δ (G″ (loss modulus)/G′ (storage modulus)) was calculated to obtain a glass transition temperature.

(Measurement of Viscosity)

The minimum melt viscosity of the adhesive film was measured with a parallel plate method by using a rheometer (“RS-1” manufactured by Haake Technik GmbH). In details, the melt viscosities were measured in a range from 40° C. to 200° C. under the conditions of gap of 100 μm, rotation plate diameter of 20 mm, rotation speed of 5s⁻¹ and rising temperature speed of 10° C./min, and the minimum value of the melt viscosities obtained from each of a range from 40° C. to 100° C. and a range from 100° C. to 200° C. was regarded as a minimum melt viscosity of each of the ranges.

[Thermal Reliability]

(1) Production of Adhesive Film Integrated with Dicing Tape

The adhesive film was pasted onto the pressure-sensitive adhesive layer of a dicing tape (trade name “V-8-T” manufactured by NITTO DENKO CORPORATION) using a hand roller to produce an adhesive film integrated with a dicing tape.

(2) Production of Semiconductor Package

A semiconductor wafer with a bump on one side was prepared in which the bump was formed on one side of the wafer. The adhesive film integrated with a dicing tape was pasted onto the bump formation surface of the semiconductor wafer with the bump on one side. The following semiconductor wafer was used as the semiconductor wafer with the bump on one side. The pasting conditions were as follows. The ratio (Y/X) of the thickness Y (=45 μm) of the underfill material to the height X (=45 μm) of the connection member was 1.

Semiconductor Wafer with the Bump on One Side

Diameter of semiconductor wafer: 8 inches

Thickness of semiconductor wafer: 0.2 mm (thickness after the rear surface of a wafer having a thickness of 0.7 mm was ground using a grinding apparatus “DFG-8560” manufactured by DISCO Corporation)

Height of bump: 45 μm

Pitch of bump: 50 μm

Pasting Conditions

Pasting apparatus: trade name “DSA840-WS” manufactured by NITTO SEIKI CO., Ltd.

Pasting speed: 5 mm/min

Pasting pressure: 0.25 MPa

Stage temperature at pasting: 80° C.

Degree of reduced pressure at pasting: 150 Pa

After pasting, the semiconductor wafer was diced under the following conditions. The dicing was performed in full cut so that the chip size became 7.3 mm square.

Dicing Conditions

Dicing apparatus: trade name “DFD-6361” manufactured by DISCO Corporation

Dicing ring: trade name “2-8-1” manufactured by DISCO Corporation

Dicing speed: 30 mm/sec

Dicing blades:

Z1; trade name “203O-SE 27HCDD” manufactured by DISCO Corporation

Z2; trade name “203O-SE 27HCBB” manufactured by DISCO Corporation

Rotations of the Dicing Blades:

Z1; 40,000 rpm

Z2; 45,000 rpm

Cutting Method: Step Cut

Size of the wafer chip: 7.3 mm square

Next, a laminate of the adhesive film and the semiconductor chip with the bump on one side (semiconductor chip with an adhesive film) was picked up with a pushing-up method by a needle from the base side of each dicing tape.

The semiconductor chip was mounted to a BGA substrate by thermal press-bonding with the bump formation surface of the semiconductor chip facing to the BGA substrate. The mounting conditions were as follows, and a process with the mounting conditions 2 was performed successively to a process with the mounting conditions 1. This provided a semiconductor package in which the semiconductor chip was mounted to the BGA substrate.

Mounting Conditions 1

Thermal press-bonding apparatus: trade name “FCB-3” manufactured by Panasonic Corporation

Heating temperature: 150° C.

Load: 10 kg

Holding time: 10 seconds

Mounting Conditions 2

Thermal press-bonding apparatus: trade name “FCB-3” manufactured by Panasonic Corporation

Heating temperature: 260° C.

Load: 10 kg

Holding time: 10 seconds

(3) Evaluation of Thermal Reliability

Ten samples of the semiconductor package according to the examples and the comparative examples were made with the above-described method, and a heat cycle at −55° C. to 125° C. for 30 minutes was repeated 500 times. Then, the semiconductor package was embedded in the epoxy resin for embedding. Next, the semiconductor package was cut in a direction perpendicular to the substrate so that the solder bonding portion was exposed, and the exposed cross section of the solder bonding portion was polished. Thereafter, the polished cross section of the solder bonding portion was observed under an optical microscope (magnification: 1,000×). The case in which the solder bonding portion was not broken was evaluated as “◯”, and the case in which the solder bonding portion was broken even one sample was evaluated as “x”. The results are shown in Table 1.

TABLE 1

| | | Example | Example | Example | Example | Comparative | Comparative |
|---|---|---|---|---|---|---|---|
| | | 1 | 2 | 3 | 4 | Example 1 | Example 2 |
| Compounding | Acrylic Resin | 100 | 100 | 100 | 50 | 100 | 100 |
| (parts by | Epoxy Resin 1 (Mₙ: 1650) | 56 | 56 | 19 | 19 | 56 | 75 |
| weight) | Epoxy Resin 2 (Mₙ: 370) | 19 | 19 | 56 | 112 | 19 | — |
| | Phenol Resin 1 (Mₙ: 550) | 75 | 50 | 30 | 20 | — | 75 |
| | Phenol Resin 2 (Mₙ: 1230) | — | 30 | 50 | 60 | — | — |
| | Phenol Resin 3 (Mₙ: 490) | — | — | — | — | 60 | — |
| | Silica Filler | 167 | 167 | 167 | 167 | 167 | 167 |
| | Organic Acid | 1.3 | 1.3 | 1.3 | 1.3 | 1.3 | 1.3 |
| | Imidazole Catalyst | 1.3 | 1.3 | 1.3 | 1.3 | 1.3 | 1.3 |
| Evaluation | Flexibility | ∘ | ∘ | ∘ | ∘ | ∘ | x |
| | Tg (° C.) | 128.0 | 143.4 | 148.0 | 145.6 | 141.1 | 135.3 |
| | Temperature (° C.) at which viscosity | 80 | 85 | 85 | 85 | 75 | 85 |
| | becomes 20,000 Pa · s or less | | | | | | |
| | (Measurement Temperature: 40 to 100° C.) | | | | | | |
| | Minimum Viscosity (Pa · s) at 100 to 200° C. | 340 | 415 | 420 | 432 | 323 | 385 |
| | Thermal Reliability | ∘ | ∘ | ∘ | ∘ | x | ∘ |

In Examples 1 and 2 in which the epoxy resin having a number average molecular weight of 600 or less (Epoxy Resin 2), the phenol resin having a number average molecular weight exceeding 500 (Phenol Resin 1 or 2), and the acrylic resin were compounded, good flexibility and good thermal reliability were obtained.

In Comparative Example 2 in which Epoxy Resin 2 was not compounded (example in which Epoxy Resin 1 was compounded in place of Epoxy Resin 2 of Example 1), the flexibility was poor although the thermal reliability was good. In Comparative Example 1 in which Phenol Resin 3 having a small molecular weight was compounded, the thermal reliability was poor although the flexibility was good.

### REFERENCE CHARACTERS LIST

1 Tape for Grinding Rear Surface
1a Base
1b Pressure-Sensitive Adhesive Layer
2 Adhesive Film for Underfill
3 Semiconductor Wafer
3a Circuit Surface of Semiconductor Wafer
3b Surface Opposite to Circuit Surface of Semiconductor Wafer
4 Connection Member (Bump)
5 Semiconductor Chip
6 Adherend
7 Conductive Material
10 Adhesive Film for Underfill Integrated with Tape for Grinding Rear Surface
11 Dicing Tape
11a Base
11b Pressure-Sensitive Adhesive Layer
30 Semiconductor Device
41 Dicing Tape
41a Base
41b Pressure-Sensitive Adhesive Layer
42 Adhesive Film for Underfill
43 Semiconductor Wafer
44 Connection Member (Bump)
45 Semiconductor Chip
46 Adherend
47 Conductive Material
50 Adhesive Film for Underfill Integrated with Dicing Tape
60 Semiconductor Device

1. An adhesive film for underfill, comprising:
resin components containing an epoxy resin having a number average molecular weight of 600 or less, a phenol resin having a number average molecular weight exceeding 500, and an elastomer;
wherein a content of the epoxy resin in the resin components is 5 to 50% by weight;
wherein a content of the phenol resin in the resin components is 5 to 50% by weight.

2. The adhesive film for underfill according to claim 1, wherein a hydroxyl equivalent weight of the phenol resin is 200 g/eq or more.

3. The adhesive film for underfill according to claim 1, wherein the phenol resin contains a skeleton represented by a following formula (I); 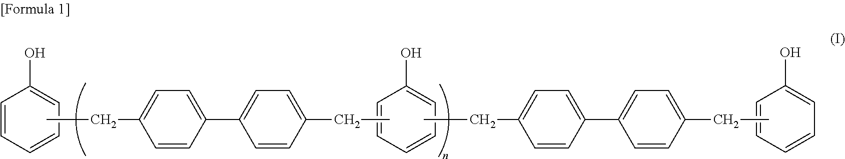
(In the formula, n represents an integer.)

4. The adhesive film for underfill according to claim 1, wherein the epoxy resin is a bisphenol A epoxy resin or a bisphenol F epoxy resin.

5. The adhesive film for underfill according to claim 1, wherein a content of the elastomer in the resin components is 10 to 40% by weight.

6. The adhesive film for underfill according to claim 1, wherein the elastomer is an acrylic resin.

7. The adhesive film for underfill according to claim 1, wherein a temperature exists at which a viscosity becomes 20,000 Pa·s or less when the viscosity is measured at 40 to 100° C.;
wherein a minimum viscosity at 100 to 200° C. is 100 Pa·s or more.

8. The adhesive film for underfill according to claim 1, further comprising an inorganic filler at 30 to 70% by weight.

9. An adhesive film for underfill integrated with a tape for grinding a rear surface, comprising:
the adhesive film for underfill according to claim 1; and
the tape for grinding the rear surface;
wherein the adhesive film for underfill is provided on the tape for grinding the rear surface.

10. An adhesive film for underfill integrated with a dicing tape, comprising:
the adhesive film for underfill according to claim 1; and
the dicing tape;
wherein the adhesive film for underfill is provided on the dicing tape.

11. A semiconductor device manufactured by using the adhesive film for underfill according to claim 1.

12. A semiconductor device manufactured by using the adhesive film for underfill integrated with the tape for grinding the rear surface according to claim 9.

13. A semiconductor device manufactured by using the adhesive film for underfill integrated with the dicing tape according to claim 10.
